(19) United States
(12) Patent Application Publication
(10) Pub. No.: US 2006/0227028 A1
(43) Pub. Date: Oct. 12, 2006

(54) Simple digital interface for advance power supply control

(76) Inventors: Laszlo Balogh, Merrimack, NH (US); Brian J. Shaffer, Lynnfield, MA (US)

Correspondence Address: TEXAS INSTRUMENTS INCORPORATED, P O BOX 655474, M/S 3999, DALLAS, TX, 75265, US

(21) Appl. No.: 11/101,165

(22) Filed: Apr. 7, 2005

(51) Int. Cl. H03M 1/66

(52) U.S. Cl. 341/144

(57) ABSTRACT

A power converter has a digital control that interfaces with an analog driver through a simple and efficient signal connection. A single signal may be used to encode frequency and pulse width information to realize a number of control functions based on the digital control algorithms. The functions of analog and digital circuitry are separated to improve flexibility in the power converter, and the interface signal provides a digital-to-analog interface for communicating control information rapidly and efficiently. The arrangement permits realization of a volt-second clamp among other programmable features that were previously set through hard wiring with passive components.

### BACKGROUND OF THE INVENTION

1. Field of the Invention

The present invention relates generally to digital control of power and supply systems, and relates more particularly to a communication interface between a digital micro-controller and analog power supply control.

2. Description of Related Art

Increase operability for control of power converters in a power management system has received increasing focus in recent years. Additional, sought after control features of power supplies appear to be gaining more prominence in the construction of power converters and power converter controllers, due to the demands of increase efficiency and reduced power losses. As the power density of power converters increases, additional control features help to maintain the integrity of power converters and their components. For example, a great deal of attention has been paid to over current conditions in power converters that may shorten the useful life of components in the converter or cause damage to system loads or components.

In a typical conventional PWM controller, control is achieved through the use of comparators in conjunction with analog to digital converters (ADCs). The comparators and ADCs provide an interface between analog and digital components, so that analog information is delivered to the controller, which converts the information to digital control logic, such as PWM signals, for application to a power switching stage. FIG. 1 illustrates this control architecture used in conventional power converters.

FIG. 2 illustrates another conceptual control for a power converter, where analog inputs are all converted through ADCs to digital representations, which are provided to a digital processor to permit the processor to generate the appropriate control signals for the power stage. The architecture illustrated in FIG. 2 provides a high level of flexibility in comparison to the system illustrated in FIG. 1, since the digital processor can be programmed to provide a wide range of responses based on the digital inputs from the ADCs and characteristics of the power stage. Controllers such as those illustrated in FIG. 1 are typically hardware programmed with the values of various components, so that manipulation of features in the controller is difficult or impractical. There are a number of other advantages provided with digital control, including increased precision of tolerances, compensation for aging and temperature effects, the ability to provide communication and data management features, and so forth. Digital processors can implement advanced control algorithms, including nonlinear control, which are difficult or impractical to implement in an analog control system. A digital control also can be used with multiple loops having multiple feed back paths, and can reduce the complexity of a circuit realization, as the functionality of the circuit is incorporated into the digital processor programs.

Once of the difficulties in providing a digital control for a power converter is providing a simple and fast control signal from the digital processor to the power stage of the power converter to realize the advantages of the digital control. Often, there is a fair amount of latency associated with the analog to digital conversion of the fed back analog signals in the controller. Accordingly, an interface between the digital processor and the power stage of the converter should be as simple and fast as possible.

### BRIEF SUMMARY OF THE INVENTION

In accordance with the present invention, there is provided an interface between a digital controller and a power stage of a power converter that is substantially reduced to a single line. Information for driving the power stage is encoded in the signals provided on the single line. The power stage decodes the signals to provide switching commands for power switches in the power stage, as well as control actions based on system feedback. Accordingly, the present invention provides an analog/digital interface for a power converter that is highly functional, simple and fast.

According to a feature of the present invention, a simple interface between a digital and analog controller is provided to set the instantaneous switching frequency and duty cycle of the analog controller based on digital control represented by a digital signal. The digital signal has minimal complexity and is easily decoded to provide analog control information in the analog controller.

According to an aspect of the present invention, current limit control can be applied in the single signal, including the provision of a dynamic current limit, a retry count, reduced switching intervals and shutdown, for example. The control reads a current feedback signal to determine an appropriate response that can be modified for different situations.

According to another aspect of the present invention, the digital/analog interface control signal represents different information based on different operating modes. For example, the information in the control signal may be interpreted differently during a startup mode than in a steady state mode. The information may also be used differently in a current limit mode when an overcurrent condition is detected.

According to another feature of the present invention, the information encoded control line is operable to implement a volt-second clamp based on the input voltage and the duty ratio of a switch. As the input voltage increases, the volt-second clamp limits the duty cycle of the signal to protect the transformer from saturation in an isolated topology.

Another advantage of the present invention is realized through the use of ports provided on a digital processor that permits the digital processor to output signals that can influence feedback parameters, such as current limit thresholds, for example. The additional control provided by the digital processor permits a high level of responsive and programmability in the system, where previous realization typically relied on hard coded parameter values through passive component selection.

### BRIEF DESCRIPTION OF THE SEVERAL VIEWS OF THE DRAWINGS

The present invention is described in greater detail below, with reference to the accompanying drawings:

FIG. 1 is a block diagram of a conventional power stage controller;

FIG. 2 is a block diagram of a conceptual digital power stage controller;

FIG. 3 is a block diagram illustrating a separation of analog and digital functions in a power converter control;

FIG. 4 is a circuit diagram of a power stage for a power converter;

FIG. 5 is a block diagram of the conceptual organization of an analog controller for a power stage;

FIG. 6 is a circuit block diagram illustrating operation of the digital/analog interface in accordance with the present invention;

FIG. 7 is a timing diagram illustrating operation of the interface in accordance with the present invention;

FIG. 8 is a timing diagram illustrating operation of the interface in accordance with another embodiment of the present invention;

FIG. 9 is a flow diagram illustrating operation of a volt-second clamp in accordance with the present invention; and

FIG. 10 is a diagram of a circuit fragment for adjusting an analog parameter in accordance with the present invention.

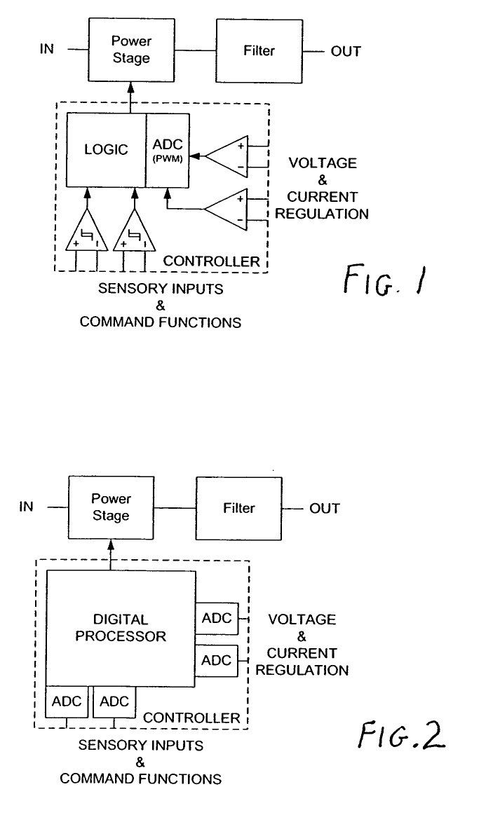

### DETAILED DESCRIPTION OF THE INVENTION

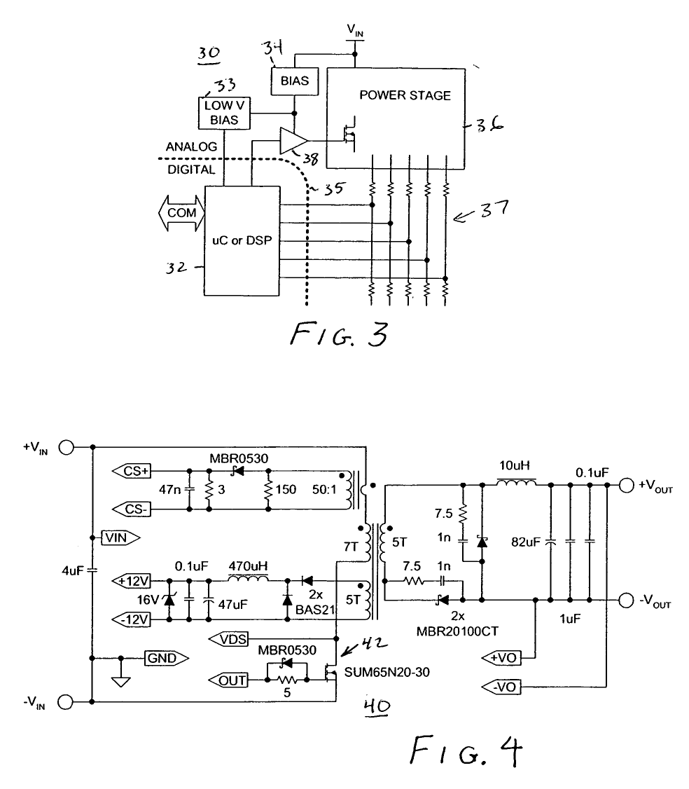

Referring now to FIG. 3, a diagram of the separation of digital and analog components in a power converter control is illustrated generally as circuit 30. A digital processor 32 such as a microcontroller or digital signal processor (DSP) resides on one side of the digital/analog boundary 35. Processor 32 receives analog feedback from power stage 36 through a resistor network 37. Processor 32 also receives a voltage bias input from a low voltage bias supply 33 that is derived from a driver voltage bias 34. Processor 32 operates on the information provided by the analog feedback in conjunction with bias 33 to provide an output signal to a driver 38 for operating a switch in power stage 36. The signal line connected between processor 32 and driver 38 provides signals that are characterized in accordance with the present invention. The signal encodes frequency and pulse width information that is decoded by driver 38 for operation of one or more switches in power stage 36.

Referring now to FIG. 4, a circuit diagram 40 illustrates a power stage for a power converter that includes a switch 42. Switch 42 is driven by the signal connected to a line labeled OUT, which is connected to the analog driver for switch 42. Circuit 40 also provides feedback signals such as CS+ and CS−, +VO and − VO and voltage bias signals +12V and −12V for use with the driver and voltage bias supply to the digital processor. The output of circuit 40 is a regulated power converter output controlled by the switching characteristics of switch 42.

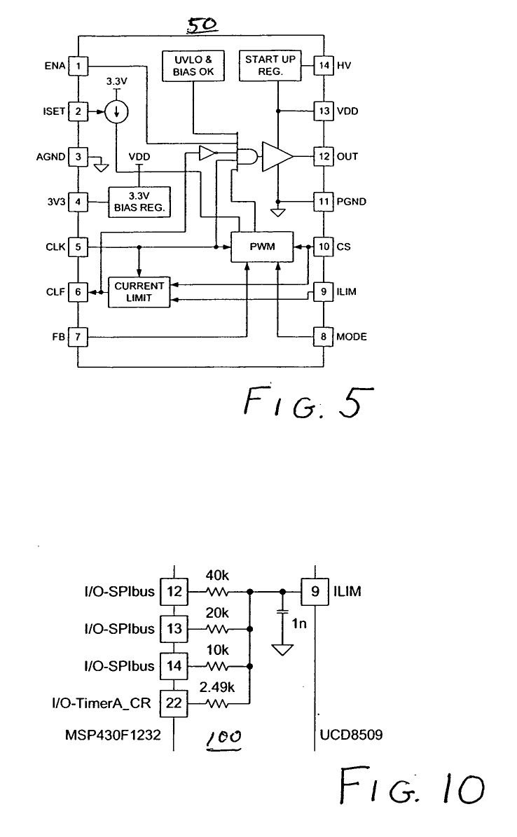

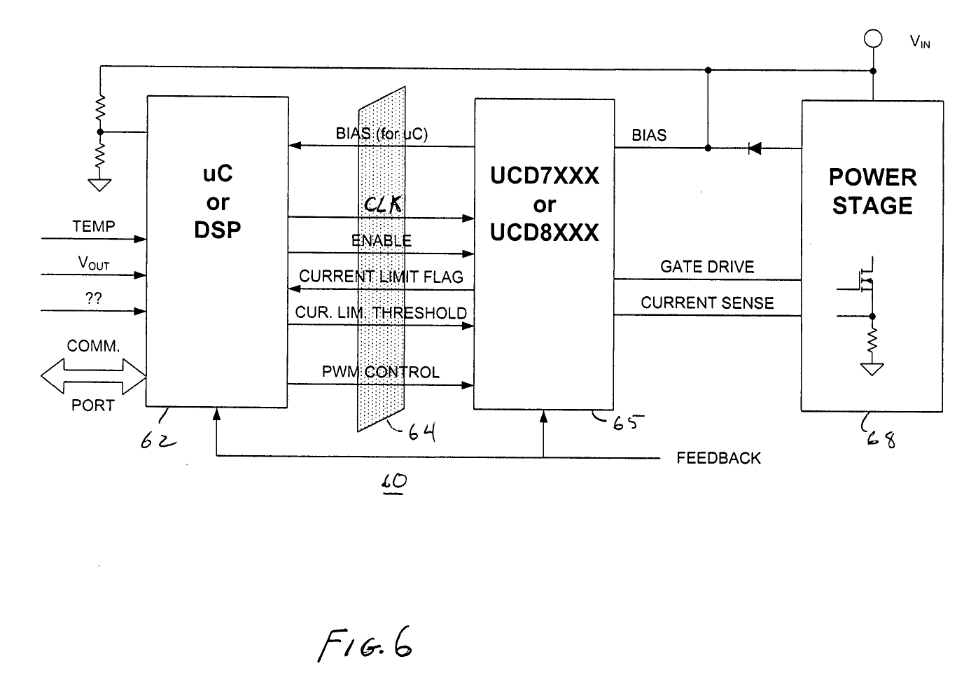

Referring now to FIG. 5, a diagram of an analog driver control is illustrated generally as circuit 50. Circuit 50 includes feedback and set point inputs CS, ILIM, MODE and FB. A single control input CLK provides the control for driver circuit 50, and is used in conjunction with PWM signals that are influenced by the circuit feedback and modes. Output OUT of circuit 50 provides the switching signal for driving a power switch in the power stage of the power converter.

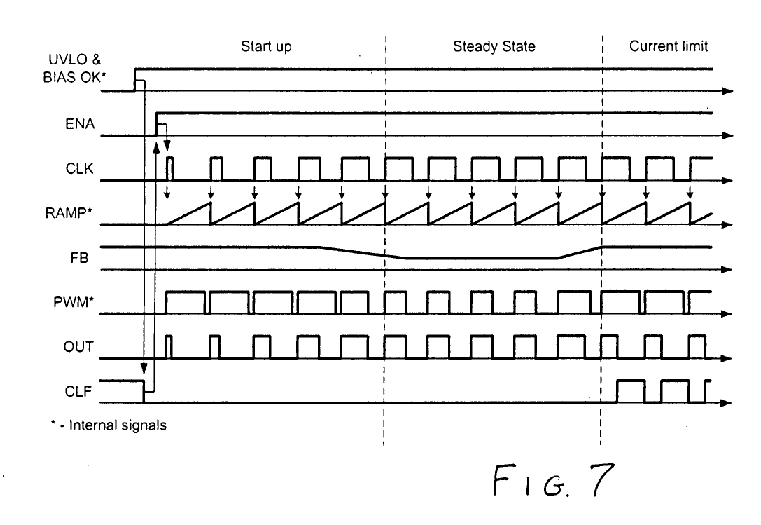

Referring now to FIG. 6, a block diagram of a control system in accordance with the present invention is illustrated as diagram 60. Diagram 60 includes a digital processor 62, an analog controller 65 and a power stage 68. Analog controller 65 provides the drive signals for the power switches in power stage 68, and may be organized similarly to circuit 50 illustrated in FIG. 5. In accordance with the present invention, analog controller 65 is responsible for a number of analog control operations in the power converter of diagram 60. Particular digital functionality is separated out of analog controller 65 for incorporation into processor 62. By separating the digital and analog control features, the present invention permits a high degree of flexibility and operability in the design and implementation of a power converter control.

Interface between processor 62 and controller 65 is extremely simple and straight forward. A signal CLK provided from processor 62 to controller 65 encodes all of the control information for instructing controller 65 to drive the power switches in power stage 68. Signal CLK is a PWM signal that is also frequency modulated, in that the frequency information of the pulse train in signal CLK provides switching information for the power switch in power stage 68. By encoding the control information in a single signal, interface 64 is greatly simplified and extremely fast in facilitating control operations between processor 62 and controller 65. Although processor 62 is also shown as providing signals for PWM control, a current limit threshold and an enable, these signals are not essential for operation of analog controller 65. Accordingly, a single control line CLK can provide complete control information from processor 62 to controller 65.

Referring now to FIG. 7, a timing diagram illustrates the control functionality of signal CLK according to an embodiment of the present invention. Signal CLK may be interpreted differently depending upon the different modes of operation, such as start up, steady state or current limit. During a start up mode, controller 65 goes through an enabling sequence where the undervoltage lock out (UVLO) state is passed, as well as a current limit check indicated by signal CLF. After signals UVLO and CLF reach an appropriate state, enable signal ENA goes to an enable state, after which signal CLK begins to drive an output of controller 65. In this embodiment, intervals between pulses in signal CLK are decoded with a sound tooth signal RAMP, which represents a linear ramp between the rising edge of the pulses in signal CLK. The ramp signal causes a reset during each pulse interval, whereby the switching frequency is determined. The width of the pulses in signal CLK limits the maximum on time of the gate drive output. Note that although signal PWM includes wide pulses, the gate drive output OUT is determined by the pulse width of signal CLK. The pulse width of signal CLK is continuously recalculated processor 62 that generates signal CLK to implement a number of control functions.

Once the power converter has moved from start up mode to steady state mode, the converter duty ratio is less than a limit imposed by processor 62. In this instance, output OUT has pulse widths determined by signal PWM. The pulse widths on signal CLK during steady state operation act as a safeguard or maximum duty cycle limit to impose a safety limit on the operation of the power converter. Note that feedback signal FB is maintained at a low level during the steady state operation.

When an overcurrent condition occurs, controller 65 enters a current limit mode, in which the duty cycle of the output OUT is limited. The current limit function provides cycle by cycle control to override the duty cycles of signal CLK, when the switch current reaches the current limit threshold. The current limit threshold is a value presented at the ILIM pin of controller 65. When the current limit circuit is activated, signal CLF goes to a high value for a remainder the switching period, and feedback is provided to controller 62 to provide an overcurrent close loop control.

It should be noted that the current limit functionality can be completely independent of signal CLK from processor 62. A current limit event can be latched in the memory of analog controller 65 until a following switching period initiated by processor 62. With this technique, controller 65 can protect the power stage in the event of a problem with processor 62. For example, if processor 62 stalls or freezes, such that signal CLK is left in a high state, the current limit circuit causes the power switch to be switched at a lower duty cycle in an overcurrent condition, regardless of signal CLK.

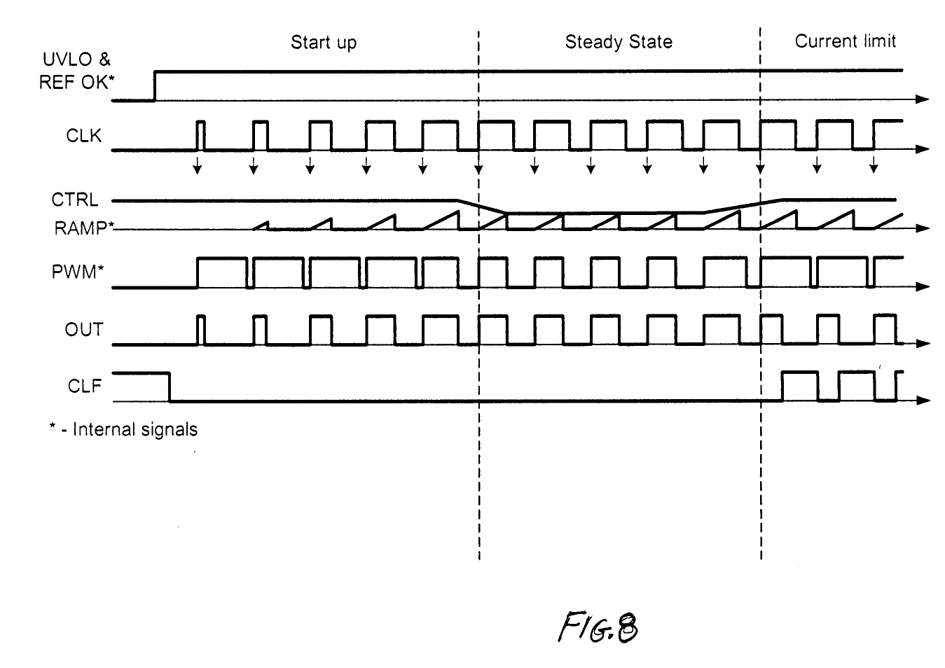

Referring now to FIG. 8, the timing diagram for another embodiment of the present invention is illustrated. In this embodiment, the signal RAMP is a linear ramp signal indicative of pulse width, rather than pulse period, or switching frequency. A control signal CTRL is used as a duty cycle clamp for limiting the ramp of internal signal RAMP. Accordingly, while signal CLK provides a limit on the duty cycle, the duty cycle of the output OUT is defined by signal RAMP, as limited by signal CTRL during steady state operation. In the event of an overcurrent condition, the output signal OUT is again limited by the current limited circuit, indicated by the current limit flag CLF.

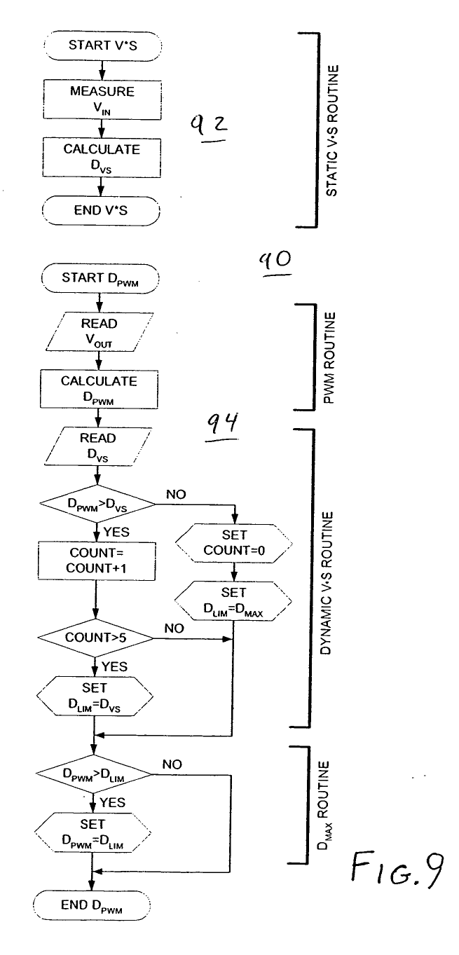

Referring now to FIG. 9, a flow diagram of functionality that can be realized using the interface according to the present invention is shown generally as diagram 90. Because the present invention provides a digital control for a power converter, an algorithm can be implemented easily to realize greater functionality in the control. Accordingly, diagram 90 illustrates the operation of a volt-second clamp used to protect the transformer from saturation in the power stage of the power converter. Diagram 90 illustrates both the static volt-second clamp routine and a dynamic volt-second clamp routine in accordance with the digital control of the present invention. A diagram 92 illustrates static volt-second clamp control. In diagram 92, input voltage VN is measured to determine a duty cycle DVS that can be applied without saturation of the transformer. When input voltage VN drops to a minimum input voltage, as defined during power stage design, duty cycle DVS is set to a maximum value of DMAX, which is typically twenty percent above the nominal duty ration of the converter. Because the volt-second clamp is static, it is fairly inflexible with respect to operating conditions and changes in circuit parameters that may occur with age, for example.

Diagram 94 illustrates a dynamic volt-second clamp routine in which output voltage is measured to determine an output voltage error, DPWM. If the duty cycle voltage error is greater than the set duty cycle limit DVS, the routine permits the converter to operate beyond the limit for five cycles, in the example illustrated in diagram 94. This temporary operation beyond the set point limits can accommodate a fast transient response to avoid reduction of the duty ratio when the operational limits are exceeded for only a short period of time. Diagram 94 shows how the limit for the volt-second clamp can be dynamically changed by setting duty ration DLIM to the current duty ration DVS, and comparing that limit against the voltage error DPWM. If duty ration DLIM is less than the voltage error, than DLIM is used as the duty ratio limit, otherwise, voltage error DPWM is set to duty ratio DLIM, so that a maximum duty ratio can be adjusted.

Referring now to FIG. 10, a circuit fragment for adjusting a current limit threshold is illustrated generally as circuit 100. Circuit 100 provides a way to override a default current limit threshold using output ports of a digital processor. The type of resistor network illustrated in circuit 100 implements a rudimentary digital to analog converter (DAC) to provide a digital method for adjusting the analog value of the current limit threshold. When any of the ports are turned on, a certain amount of current is sinked, causing a relative reduction in the default current limit threshold.

In an overload condition, the duty cycle of the power switch in the power stage is limited by the current limit circuit on a cycle by cycle basis. If the current sent signal reaches a limit set by the current limit threshold, the gate drive is immediately shut off to protect the power stage. Accordingly, a shut off threshold can be dynamically altered depending upon the type of loading or overcurrent event that the power converter experiences.

The present invention describes a simple and effective interface between a digital controller and an analog controller. The interface can be implemented in a single control line that carries frequency and pulse width information for driving the analog controller. This architecture is applicable to a number of situations in which analog systems are controlled with digital techniques. Accordingly, power converters, motor drives, lighting systems and other power applications are ready candidates for digital control with the interface provided according to the present invention.

Finally, it will be appreciated that modifications to and variations of the above-described system and method may be made without departing from the inventive concepts disclosed herein. Accordingly, the invention should not be viewed as limited except by the scope and spirit of the appended claims.

What is claimed is:

1. An interface for communication between a digital and an analog device, comprising:
a signal path for transferring information from the digital device to the analog device;
a signal with a characteristic suitable for transmission through the signal path and encoding the information;
a signal encoder in the digital device and coupled to the signal path for generating the information encoded signal and transmitting the signal on the signal path; and
a signal receiver in the analog device coupled to the signal path for receiving the signal and processing the encoded information.

2. The interface according to claim 1, wherein the signal encoder is operable to encode one or more of a switching frequency or pulse width.

3. The interface according to claim 1, wherein the digital device is a digital processor.

4. The interface according to claim 1, wherein the analog device is a driver circuit for a power switch.

5. The interface according to claim 4, wherein the information encoded signal influences switching of the power switch.

6. The interface according to claim 1, wherein the information encoded signal is operable to realize a volt-second clamp function.

7. A method for transmitting information between a digital device and an analog device, comprising:
encoding a digital signal with information related to switching a power switch;
transmitting the digital signal to the analog device; and
driving the power switch through operation of the analog device in conjunction with the digital signal.

8. The method according to claim 7, wherein encoding further comprises modulating a frequency and a pulse width of a digital pulse train.

9. The method according to claim 7, further comprising realizing a volt-second clamp through application of the digital signal to the analog device.

10. A power converter with a digital control, comprising:
a power switch for controlling energy transfer in the power converter;
an analog controller coupled to the power switch and operable to provide drive signals to the power switch
a digital processor coupled to the analog controller for generating and transmitting a digital control signal to the analog controller; and
the digital control signal encodes control information useable by the analog controller to contribute to control of the power switch.

11. The converter according to claim 10, wherein the digital control signal includes frequency and pulse width information to encode the control information.
